(19) United States
(12) Patent Application Publication
(10) Pub. No.: US 2009/0221150 A1
(43) Pub. Date: Sep. 3, 2009

(54) ETCH RATE AND CRITICAL DIMENSION UNIFORMITY BY SELECTION OF FOCUS RING MATERIAL

(75) Inventors: Edward P. Hammond, IV, Hillsborough, CA (US); Jing Zou, Sunnyvale, CA (US); Rodolfo P. Belen, San Francisco, CA (US); Meihua Shen, Fremont, CA (US); Nicolas Gani, San Jose, CA (US); Andrew Nguyen, San Jose, CA (US); David Palagashvili, Mountain View, CA (US); Michael D. Willwerth, Campbell, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/395,465

(22) Filed: Feb. 27, 2009

Related U.S. Application Data
(60) Provisional application No. 61/032,920, filed on Feb. 29, 2008.

(51) Int. Cl. H01L 21/3065; C23F 1/08

(52) U.S. Cl. 438/710; 156/345.51; 156/345.28; 257/E21.218

(57) ABSTRACT

A method and apparatus are provided for plasma etching a substrate in a processing chamber. A focus ring assembly circumscribes a substrate support, providing uniform processing conditions near the edge of the substrate. The focus ring assembly comprises two rings, a first ring and a second ring, the first ring comprising quartz, and the second ring comprising monocrystalline silicon, silicon carbide, silicon nitride, silicon oxycarbide, silicon oxynitride, or combinations thereof. The second ring is disposed above the first ring near the edge of the substrate, and creates a uniform electric field and gas composition above the edge of the substrate that results in uniform etching across the substrate surface.

### CROSS-REFERENCE TO RELATED APPLICATIONS

This application claims benefit of U.S. provisional patent application Ser. No. 61/032,920, filed Feb. 29, 2008, which is herein incorporated by reference.

### BACKGROUND OF THE INVENTION

1. Field

Embodiments of the present invention relate to the field of semiconductor substrate processing system. More specifically, the invention relates to a focus ring assembly suitable for use in a substrate process chamber.

2. Description of the Related Art

For more than half a century, the semiconductor industry has followed Moore's Law, which states that the density of transistors on an integrated circuit doubles about every two years. Continued evolution of the industry along this path will require smaller features patterned onto substrates. As feature size shrinks, manufacturers are challenged to maintain control of device properties and performance. Maintaining control of critical dimensions of features on a semiconductor substrate is a fundamental requirement of etching processes used to form those features. During a plasma etch process, for example, the critical dimension (CD) could be the width of a gate structure, trench or via and the like.

As technology nodes advance and critical dimensions shrink, increasing emphasis is placed on reducing the amount of edge-exclusion on a substrate. Edge-exclusion refers to the area near the edge of a substrate in which no features or devices are formed. Reducing edge-exclusion provides space for forming additional devices nearer the edge of a substrate. As structures are formed closer to the edge, maintaining CD uniformity across the substrate during etching processes becomes more difficult. A common form of CD non-uniformity is known as “edge roll-off”, which features a dramatic reduction in CD control close to the edge of the substrate. Additionally, CD bias—the change in CD as successive layers are etched—declines near the edge.

Current plasma etch processes attempt to address this problem by providing a “focus ring” near the edge of the substrate that has similar composition to the substrate. It is thought that the focus ring behaves as an “extension” of the film being etched and promotes a uniform concentration of etch by-product species across the substrate. This, in turn, promotes a more uniform etch rate. In etch chambers that etch silicon, for example, it is common to use a quartz focus ring due to the low etch rate of quartz relative to the substrate material and its lack of contaminants. Quartz, however, allows residual non-uniformity that becomes increasingly important as devices, and edge-exclusion, become smaller.

Thus, there is a need for an apparatus that enhances etch performance at the edge of a substrate.

### SUMMARY

Embodiments of the invention include a processing chamber for etching a substrate. In one embodiment, the processing chamber includes a chamber body having a substrate support disposed on a cathode. An electrode is disposed in the cathode and has a diameter greater than the substrate support. A focus ring is disposed on an upper surface of the substrate support. The focus ring is comprised of a material selected from the group consisting of silicon, monocrystalline silicon, silicon carbide, silicon nitride, silicon oxycarbide, and combinations thereof. A quartz ring is disposed on the upper surface of the substrate support and circumscribes the focus ring.

In one embodiment of a processing chamber, the focus ring includes a substantially vertical inner wall at an inner radius, a first surface extending from the inner wall in an orientation substantially perpendicular thereto. A first step extends from the first surface and is substantially perpendicular thereto. A second surface extends from the first step and is substantially perpendicular thereto. A bevel extends from the second surface and forms an angle less than about 80° with the second surface. The second surface extends from the first step to the bevel a distance between about 0.08 inches and about 0.14 inches. An upper surface of the focus ring extends from the bevel and is substantially parallel to the second surface.

Other embodiments of the invention provide methods for etching a substrate. In one embodiment, a method for etching a substrate includes providing one or more etchants to a process chamber; establishing an electric field in the chamber using RF power; and focusing the electric field using a focus ring assembly comprising a first ring and a second ring, wherein the first ring comprises quartz, the second ring comprises silicon, and the second ring is conductive.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a process chamber.

FIG. 2A is a partial cross-sectional view of one embodiment of a substrate support of the process chamber of FIG. 1.

FIG. 2B is a detail view of one embodiment of a focus ring assembly.

FIG. 3A is a close-up cross-sectional view of a focus ring assembly according to one embodiment of the invention.

FIG. 3B is a close-up cross-sectional view of another focus ring assembly embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

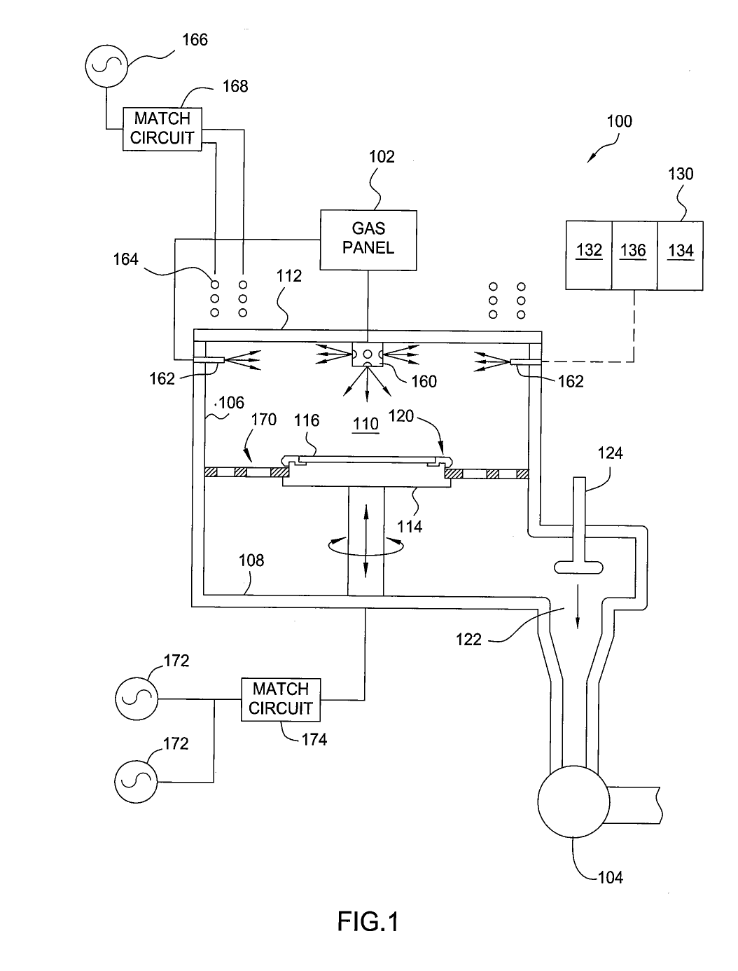

Embodiments of the invention generally provide a chamber for etching a substrate in a semiconductor manufacturing process. FIG. 1 is a schematic cross-sectional view of an exemplary process chamber 100 having a focus ring assembly 120 according to one embodiment of the invention. The process chamber 100 has a chamber body comprising sidewalls 106 and a bottom 108 that partially define a process volume 110 upwardly closed by a lid 112. The process chamber 100 is coupled to a gas panel 102, a vacuum pump 104, and a controller 130. A substrate support assembly 114 with a substrate support 116 is provided approximately at a central region of the process volume 110 to support a substrate (not shown) during processing. The focus ring assembly 120 is supported on the substrate support assembly 114 and circumscribes the substrate. One or more gas distributors are disposed in the chamber above the substrate support assembly 114 to provide process and other gases into the process volume 110. The gas distributor may be one or more nozzles or ports formed in the chamber lid and/or sidewalls 106. In the embodiment depicted in FIG. 1, the gas distributor includes a gas distribution nozzle 160 provided on an inner side of the lid 112 and a plurality of peripheral nozzles 162 formed in the sidewalls 106 to flow and distribute a processing gas supplied from the gas panel 102. Gases entering the process volume 110 from the nozzles 160, 162 may be independently controlled. In one embodiment, the radial and downward flow from the upper nozzle 160 can also be independently controlled. The processing gas is flowed from the nozzles 160, 162 toward the substrate support assembly 114, and is evacuated via the vacuum pump 104 through an exhaust port 122 located offset to the side of the substrate support assembly 114. A throttle valve 124 disposed in the vicinity of the exhaust port 122 is used in conjunction with the vacuum pump 104 to control the pressure in the process volume 110. A flow equalizing plate 170 which also functions as a plasma screen is provided to correct flow asymmetries across the surface of the substrate due to the offset port 122.

One or more antennas or coils 164 are provided proximate the lid 112 of the process chamber 100. In the embodiment depicted in FIG. 1, two coils 164 are coupled to at least one RF power source 166 through a match circuit 168. Power, applied to the coils 164, is inductively coupled to the process and other gases provided in the process chamber 100 to form and/or sustain a plasma therein. In one embodiment, power is provided to the coils 164 at 13.56 MHz.

One or more bias power sources 172 are coupled to the substrate support assembly 114 to bias the substrate during processing and/or the substrate support assembly 114 during chamber cleaning. In the embodiment depicted in FIG. 1, two RF power sources 172 are coupled to the substrate support assembly 114 through a match circuit 174. The power sources 172 may be configured to provide power to the substrate support assembly 114 at different frequencies, for example, respectively at 60 MHz and 13.56 MHz.

The controller 130 generally includes a memory 132, a CPU 134 and support circuits 136. The CPU 134 may be one of any form of computer processor that can be used in an industrial setting for controlling various chambers and subprocessors. The support circuits 136 are coupled to the CPU 134 for supporting the processor in a conventional manner. These circuits include cache, power supplies, clock circuits, input/output circuitry, subsystems, and the like. The memory 132 is coupled to the CPU 134. The memory 132, or computer-readable medium, may be one or more of readily available memory such as random access memory (RAM), read only memory (ROM), floppy disk, hard disk, or any other form of digital storage, local or remote. Instructions for performing processes may be stored on the memory 132. The instructions, when executed by the controller, cause the processing system to perform a process, such as an etch process described further below.

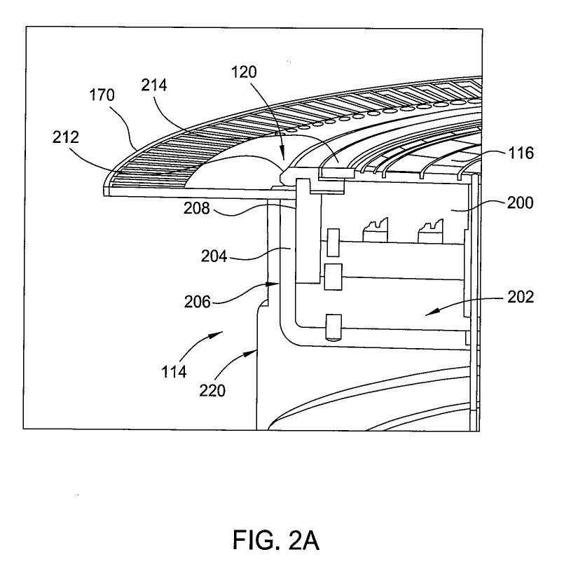

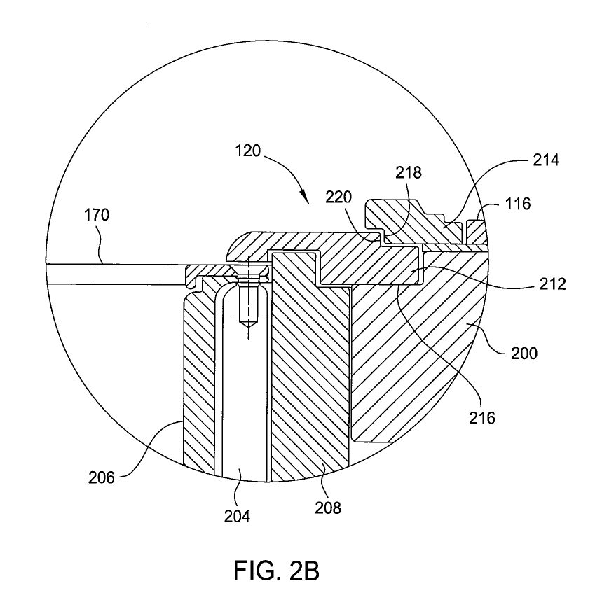

FIG. 2A is a partial cross-sectional view of the substrate support assembly 114. The substrate support assembly 114 includes a shield 220, a cathode shell 204, a cathode 200, and a substrate support 116 disposed on the cathode 200. The cathode 200 is generally fabricated from a conductive material, such as a metal or metal alloy, and generates a DC bias on the substrate support 116, thereby biasing a substrate disposed on the substrate support 116. In this embodiment, the cathode shell 204 extends beyond an edge of the substrate support 116 and the cathode 200. The cathode shell 204 includes an upper wall that extends upward to retain the cathode 200 and substrate support 116. The cathode shell 204 is held in a pocket 206 formed between the shield 220 and an isolator 208. The shield 220 may be coupled to the chamber bottom 108 (FIG. 1). The shield 220 is generally fabricated from a conductive material, such as a metal or metal alloy, which in some embodiments may be aluminum, and may also be coated with a material comprising yttrium.

Isolators 208 and 202 are disposed between the cathode shell 204 and the cathode 200. The isolators 208 and 202 generally comprise an electrically insulating material, such as quartz, and function to isolate the cathode 200 from the cathode shell 204.

A focus ring assembly 120 is shown engaging the edge of the substrate support 116. The focus ring assembly 120 includes a first ring 212, which may be an annular base ring, and a second ring 214, which may be an annular focus ring.

FIG. 2B is a detail view of a focus ring assembly 120 according to one embodiment of the invention. The first ring 212 is supported on a step 216 formed in the cathode 200. In some embodiments, the first ring 212 may rest on the step 216 of the cathode 200. Configuring the first ring 212 to rest on the step 216 of the cathode 200 may help reduce intrusion of process gases and plasma into spaces adjoining beneath the cathode 200. In some embodiments, the first ring 212 also extends beyond the edge of the cathode 200 to a point above the cathode shell 204. The second ring 214 rests substantially inside the first ring 212, such that the first ring 212 substantially circumscribes the second ring 214. The first ring is disposed at the edge of the cathode 200, and confronts the substrate support 116. The first ring may engage the surface of the cathode 200. In the embodiment of FIG. 2B, a step portion or notch 218 of the second ring 214 engages the first ring 212 at step portion 220, thus allowing the rings to mesh together if required during processing.

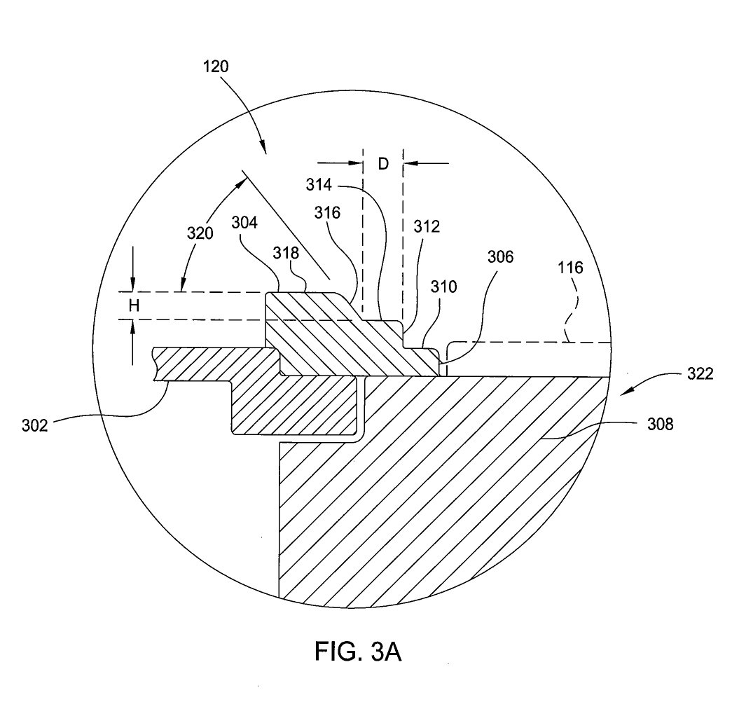

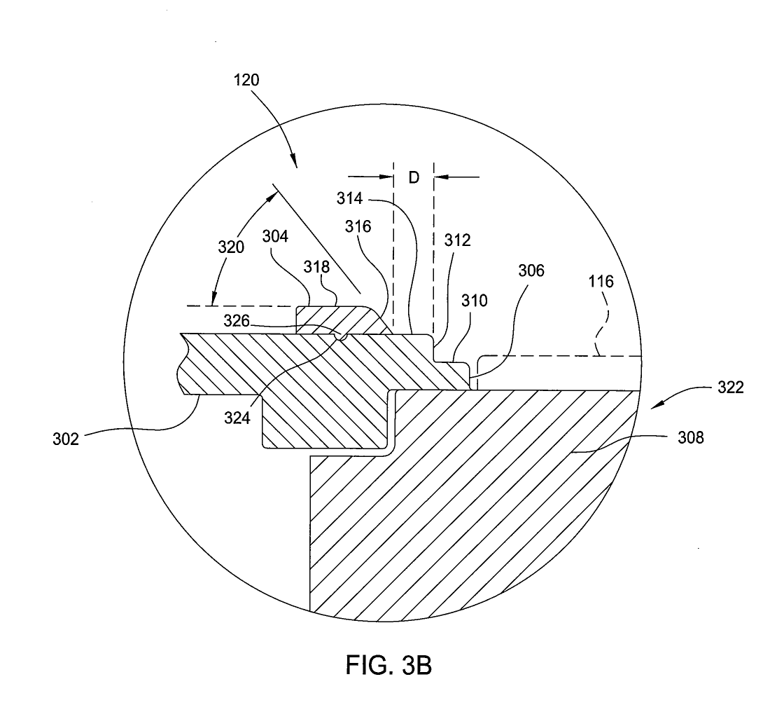

FIG. 3A is a close-up cross-sectional view of another focus ring assembly. The focus ring assembly of FIG. 3A is substantially similar to the ring assembly 120. The focus ring assembly includes a first ring 302 engaged with a second ring 304. In this embodiment, the second ring 304 is shown resting on the first ring 302 to prevent entry of etchants and etch by-products between the rings 302, 304. The first and second rings 302 and 304 are generally disposed above a substrate support assembly 322, which comprises the substrate support 116 and a cathode 308. The second ring 304 has an inner wall 306 that confronts the edge of the substrate support 116. A first surface 310 extends from the inner wall 306 and is substantially perpendicular thereto. A first step 312 extends from the first surface 310 in an orientation substantially perpendicular thereto. A second surface 314, substantially parallel to the first surface 310, and substantially perpendicular to the first step 312, extends a distance D from the first step. A second step 316 extends a height H from the second surface to a third surface 318. The distance D is generally less than about 0.15 inches, such as between about 0.08 inches and about 0.14 inches, for example about 0.11 inches. The height H is generally less than about 0.15 inches, such as between about 0.06 and 0.12 inches, for example about 0.09 inches. The second step 316 may be a bevel, and may form an angle 320 generally less than about 80° with the third surface 318 of the second ring 304. In one embodiment, the angle 320 may be between about 45° and about 75°, for example about 60°. In alternate embodiments, the first surface 310 and the first step 312 may be merged to form part of the internal wall 306, such that the second ring comprises an internal wall such as wall 306, a step surface such as surface 314 extending from the internal wall, and a step such as step 316 rising from the step surface to a top surface such as third surface 318.

The first and second rings 302 and 304 are generally disposed above an upper surface of the substrate support assembly 322. In some embodiments, the first and second rings 302 and 304 are disposed above an upper surface of the cathode 308. In one aspect, the first ring 302 may contact the upper surface of the cathode 308. In another aspect, the second ring 304 may contact the upper surface of the cathode 308. In another aspect, both rings may contact the upper surface of the cathode 308.

The first ring 302 of FIG. 3A is made of a material that will withstand processing conditions in the process chamber 100 described above. Embodiments of the focus ring assemblies described herein are generally useful in etch chambers that perform etching of gate or memory structures, including hard mask, anti-reflective, and silicon layers. Materials of construction for the first ring must therefore be able to withstand the conditions prevailing during such etching processes. The first ring must also refrain from introducing contaminants into the chamber as etching proceeds. An exemplary material for the first ring is quartz, although any material meeting these conditions would be suitable.

The second ring 304 of FIG. 3A is generally made of a material similar to that being etched. The second ring 304 improves etch uniformity by creating a vapor phase above the edge of the substrate that is similar in composition to that above other portions of the substrate. The second ring is also generally made of a material that has substantial electrical conductivity. This also improves etch uniformity by smoothing electric field lines near the edge of the substrate so as to avoid angled or tilted incidence of etchants at the surface of the substrate. An exemplary material for the second ring is silicon or monocrystalline silicon, which possesses both properties. Alternate embodiments may use silicon carbide, silicon nitride, or silicon oxycarbide. These materials will etch more slowly than silicon or monocrystalline silicon.

FIG. 3B is a close-up cross-sectional view of another focus ring assembly embodiment. The embodiment of FIG. 3B features a first ring 302 and a second ring 304 that have a different relationship to the substrate support 116 and cathode 308. The second ring 304 does not contact the cathode 308 in the embodiment of FIG. 3B, and the inner radius of the second ring 304 is larger than the inner radius of the first ring 302. In the embodiment of FIG. 3A, the inner radius of the second ring 304 is smaller than the inner radius of the first ring 302. The second ring 304 may have an inner radius that is larger or smaller than the inner radius of the first ring 302, or the two radii may be substantially the same. In the embodiment of FIG. 3B, the step 316 of the second ring 304 forms an inner wall. In general, the innermost extent of the second ring 304, such as the step 316 in the embodiment of FIG. 3B or the internal wall 306 in the embodiment of FIG. 3A, may be located a distance less than about 0.6 inches from the edge of the substrate support 116, such as between about 0 inches and about 0.6 inches from the edge of the substrate support 116, such as between about 0.2 inches and about 0.4 inches, for example about 0.3 inches. The first and second rings are positioned accurately with respect to each other by virtue of one or more recesses 324 formed in a surface of the first ring and one or more extensions 326 formed in a surface of the second ring to mate with the recess 324. The recess 324 may be a groove, such as a continuous circumferential groove, a broken or discontinuous groove, or a series of recesses spaced circumferentially around the first ring, with the extension 326 formed to match. In alternate embodiments, the recess 324 may be a radial groove or grooves, with matching extension 326. In other embodiments, the one or more recesses may be formed in the second ring, and the one or more extensions formed in the first ring.

The recess 324 and extension 326 of FIG. 3B is shown with a round or semi-circular profile, but any suitable profile may be used. For example, the recess and extension may have a square or rectangular profile, a triangular profile, or a profile of any convenient shape with monotonically diminishing width.

Wishing not to be bound by theory, it is believed that the second ring provides a passivating function for an etch process. Felicitous choice of materials for the second ring influences electric field lines and plasma density near the edge of a substrate disposed on the substrate support. Materials similar to the material of the substrate being etched provide a substantially continuous electrical and chemical environment for maintaining the plasma, promoting uniform plasma composition and uniform etch rates. The location of the second ring also influences etch rate near the edge of the substrate, with distance between the second ring and the substrate providing a way to influence plasma behavior near the substrate edge. Depending on the etch conditions and chamber geometry, a larger or smaller distance may provide suitable results.

Other embodiments of the present invention provide a method of etching a substrate, comprising providing one or more etchants to a process chamber establishing an electric field in the chamber using RF power, inductively coupling the RF power to form a plasma from the etchants and focusing the electric field using a focus ring assembly disposed on a substrate support assembly, the focus ring assembly comprising a first ring and a second ring, wherein the first ring comprises quartz, the second ring is conductive and comprises silicon. A substrate may be provided to a process chamber having a substrate support, a gas distribution assembly, a means for generating RF power such as electrodes coupled to an RF generator, and a focus ring assembly. The focus ring assembly acts to smooth the electric field lines and normalize the composition of the gas phase above the edge of the substrate.

In one embodiment, a substrate is disposed on a substrate support in an etch chamber. A first etchant selected to etch a silicon nitride hard mask layer is provided to the chamber. The first etchant may be a halogenated hydrocarbon or mixture thereof, such as a C₁-C₄ linear or cyclic fluorocarbon. Examples of such etchants are CF₄ and CHF₃. RF power is applied to coils to generate an electric field in the chamber to inductively activate the etchant. The activated etchant reacts with a silicon nitride hard mask layer disposed on the substrate, exposing a layer beneath. The etchant also reacts with the material of the second ring to generate vapor species similar to that generated above the substrate. Because the vapor chemistry above the second ring is similar to that above the edge of the substrate, activated species in the vapor phase are not concentrated or diluted above the edge of the substrate, relative to other portions of the substrate. Thus, etch rate and critical dimension uniformity are enhanced. Additionally, because the second ring is conductive and has a beneficial geometry, electric field lines are not distorted near the edge of the substrate by a difference in conductivity between the second ring and the substrate. Activated species in the vapor thus respond to the uniform electric field lines by etching the edge of the substrate surface at substantially the same rate as the center of the substrate.

In some embodiments, it may be advantageous to perform a reconditioning process on the second ring. During substrate processing, the second ring may develop impurities on its surface that are deposited from the vapor phase. These impurities may result in “micromasking” on the surface of the ring, leading to formation of a porous or grass-like structure that can generate particles in the chamber. Such impurities may be removed by using a cleaning process in which the second ring is etched under a high bias power. In one embodiment, a silicon ring may be etched with a sacrificial substrate disposed in the chamber using a fluorocarbon etchant such as CF₄ or CHF₃ under an electrical bias of between 100 watts and 3000 watts combined power for the dual frequency bias, such as about 500 watts at 13 MHz or about 1000 watts at 60 MHz, to remove the impurities.

While the foregoing is directed to embodiments of the present invention, other and further embodiments of the invention thus may be devised without departing from the basic scope thereof, and the scope thereof is determined by the claims that follow.

What is claimed is:

1. A processing chamber for etching a substrate, comprising:
a chamber body having a substrate support disposed on a cathode;
an electrode disposed in the cathode and having a diameter greater than the substrate support;
a focus ring disposed on an upper surface of the substrate support, the focus ring comprising a material selected from the group consisting of monocrystalline silicon, silicon carbide, silicon nitride, silicon oxycarbide, and combinations thereof; and
a quartz ring disposed on the upper surface of the substrate support and circumscribing the focus ring.

2. The chamber of claim 1, wherein the focus ring has an internal wall at an inner diameter, a first surface extending from the inner wall, a step rising from the first surface, and a second surface extending from the step, wherein the second surface has horizontal dimension less than about 0.15 inches.

3. The chamber of claim 2, wherein the second surface has horizontal dimension between about 0.08 inches and about 0.14 inches.

4. The chamber of claim 2, wherein the focus ring has a bevel extending from the second surface that forms an angle with the second surface of less than about 80 degrees.

5. The chamber of claim 4, wherein the angle is between about 50° and about 70°.

6. The chamber of claim 1, wherein the focus ring has an upper surface having an elevation less than about 0.2 inches above the upper surface of the substrate support.

7. The chamber of claim 1, wherein the focus ring has an annular shape and comprises:
a substantially vertical inner wall at an inner radius;
a first surface extending from the inner wall in an orientation substantially perpendicular thereto;
a first step extending from the first surface and substantially perpendicular thereto;
a second surface extending from the first step in an orientation substantially perpendicular thereto;
a bevel extending from the second surface and forming an angle less than about 80° with the second surface; and
an upper surface extending from the bevel in an orientation substantially parallel to the second surface, wherein the second surface extends from the first step to the bevel a distance between about 0.08 inches and about 0.14 inches.

8. The chamber of claim 1, wherein the focus ring is fabricated from silicon.

9. The chamber of claim 7, wherein the focus ring further comprises a notch on a lower surface of the focus ring.

10. A chamber for etching a substrate, comprising:
a chamber body having a substrate support disposed on a cathode;
an electrode disposed in the cathode and having a diameter greater than the substrate support;
a focus ring disposed above an upper surface of the cathode, the focus ring comprising a material selected from the group consisting of silicon, silicon carbide, silicon nitride, silicon oxycarbide, and combinations thereof; and
a quartz ring disposed above the upper surface of the cathode and circumscribing the focus ring, wherein the focus ring further comprises:
a substantially vertical inner wall at an inner radius;
a first surface extending from the inner wall in an orientation substantially perpendicular thereto;
a first step extending from the first surface in an orientation substantially perpendicular thereto;
a second surface extending from the first step in an orientation substantially perpendicular thereto;
a bevel extending from the second surface and forming an angle less than about 80 degrees with the second surface; and
an upper surface extending from the bevel and substantially parallel to the second surface, wherein the second surface extends from the first step to the bevel a distance between about 0.08 inches and about 0.14 inches.

11. The chamber of claim 10, further comprising a source of a halogenated hydrocarbon etchant arranged to provide the etchant into the chamber body, a controller, and computer readable media, wherein the controller is configured to execute instructions contained in the computer readable media to cause a process to be performed in the process chamber, the process comprising:
providing one or more etchants to a process chamber;
establishing an electric field in the chamber using RF power; and
focusing the electric field using the focus ring assembly.

12. The chamber of claim 10, wherein the quartz ring contacts the upper surface of the cathode.

13. The chamber of claim 10, wherein the quartz ring contacts the focus ring.

14. The chamber of claim 10, wherein the quartz ring and the focus ring each contacts the upper surface of the cathode.

15. A method of etching a substrate, comprising:
providing one or more etchants to a process chamber;
establishing an electric field in the chamber using RF power; and
focusing the electric field using a focus ring assembly comprising a first ring and a second ring, wherein the first ring comprises quartz, the second ring comprises silicon, and the second ring is conductive.

16. The method of claim 15, further comprising reconditioning the second ring.

17. The method of claim 16, wherein reconditioning the second ring comprises exposing the second ring to a second etchant after the substrate is removed from the chamber body.

18. The method of claim 15, wherein the second ring comprises a material selected from the group consisting of monocrystalline silicon, silicon carbide, silicon nitride, silicon oxycarbide, silicon oxynitride, and combinations thereof.

19. The method of claim 17, wherein the one or more etchants are selected from the group consisting of CF₄, CHF₃, and combinations thereof.

20. The method of claim 19, further comprising applying an electrical bias to the substrate support while reconditioning.

21. The chamber of claim 1, wherein the quartz ring has an inner radius that is larger than an inner radius of the focus ring.
